(19) United States
(12) Patent Application Publication
(10) Pub. No.: US 2006/0275975 A1
(43) Pub. Date: Dec. 7, 2006

(54) Nitridated gate dielectric layer

(76) Inventors: Matt Yeh, Hsinchun (TW); Da-Yuan Lee, Kaohsiung City (TW); Chi-Chun Chen, Kaohsiung (TW); Jin Ying, Singapore (SG); Shih-Chang Chen, Hsin-Chu (TW)

Correspondence Address: SLATER & MATSIL, L.L.P., 17950 PRESTON ROAD, SUITE 1000, DALLAS, TX, 75252, US

(21) Appl. No.: 11/142,488

(22) Filed: Jun. 1, 2005

(51) Int. Cl. H01L 21/8238

(52) U.S. Cl. 438/216

(57) ABSTRACT

A metal-oxide-semiconductor field-effect transistors (MOSFET) with a gate structure having a deuterated layer is provided. In accordance with embodiments of the present invention, a transistor comprises the deuterated layer formed over a gate dielectric layer. A gate electrode is formed over the deuterated layer. The deuterated layer prevents or reduces dopant penetration into a substrate from the gate electrode. The deuterated layer may be, for example, formed by a thermal process in an ambient of a deuterated gas, such as deuterated ammonia. The deuterated layer may also be formed by a nitridation process using deuterated ammonia.

### TECHNICAL FIELD

The present invention relates generally to semiconductor devices, and more particularly, to metal-oxide-semiconductor field-effect transistors and methods of manufacture.

### BACKGROUND

Size reduction of metal-oxide-semiconductor field-effect transistors (MOSFETs), including reduction of the gate length and gate oxide thickness, has enabled the continued improvement in speed, performance, density, and cost per unit function of integrated circuits over the past few decades. Typically, the MOSFETs are fabricated on a silicon semiconductor substrate. Decreasing the device sizes, however, may cause problems that cause the devices to fail.

One problem is a phenomena referred to as the time-dependent degradation, which is also referred to as the hot-carrier degradation effect. This problem is caused by dangling bonds (unsaturated silicon bonds) in the silicon substrate. Over time, dopant from the gate electrode penetrates into the silicon substrate and bonds with the unsaturated silicon bonds. As the charge carriers are removed from the gate electrode, the electrical characteristics of the device changes and, over time, the device may fail.

To reduce this effect, attempts have been made to introduce nitrogen atoms into the silicon dioxide (e.g., the gate oxide) to prevent or reduce the undesirable penetration of dopant from the gate electrode into the silicon dioxide. One attempt uses ammonia to nitridate the silicon dioxide. Nitrided oxide, however, has some undesirable characteristics, such as high-density fixed charges located at the interface between the gate oxide and the substrate and high-density electron traps will result in mobility degradation.

Another attempt introduces an anneal in an ambient comprising deuterium. The anneal, however, was performed post-metal and introduced another annealing process. The annealing process at this stage is inefficient and may reduce yields.

Therefore, there is a need for an efficient and cost-effective method to prevent or reduce the penetration of dopant into the substrate.

### SUMMARY OF THE INVENTION

These and other problems are generally reduced, solved or circumvented, and technical advantages are generally achieved, by embodiments of the present invention, which provides a deuterated layer between a gate oxide and a gate electrode.

In an embodiment of the present invention, a metal-oxide-semiconductor field-effect transistor (MOSFET) having a gate dielectric layer that comprises a deuterated layer is provided. The MOSFET comprises a gate oxide formed over a substrate. A deuterated layer, such as a layer of deuterated oxynitride, is positioned over the gate oxide and the gate electrode is positioned over the deuterated oxynitride. The deuterated layer prevents or reduces the dopant migration from the gate electrode to the substrate.

In another embodiment of the present invention, a method of fabricating a MOSFET with a gate structure having a deuterated layer is provided. The method comprises forming a dielectric layer over a substrate, and transforming at least a portion of the dielectric layer into a deuterated layer. A conductive layer is formed over the deuterated layer. These layers may then be patterned to form the gate structure. Thereafter, source/drain regions and spacers may be formed.

In yet another embodiment of the present invention, a method of fabricating a MOSFET with a gate structure having a deuterated layer in a core region is provided. The method comprises forming a first dielectric layer in a first region and a second region on a substrate. A second dielectric layer is formed on the first dielectric in the second dielectric layer formed over the first dielectric layer. Thereafter, at least a portion of the second dielectric may be treated with a hydrogen isotope, such as deuterium.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The object and other advantages of this invention are best described in the preferred embodiment with reference to the attached drawings that include:

FIGS. 1-3 illustrate various process steps of fabricating a MOSFET device having a gate structure with a deuterated layer; and

FIGS. 4-9 illustrate various process steps of fabricating a MOSFET device having a gate structure with a deuterated layer in a core region.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

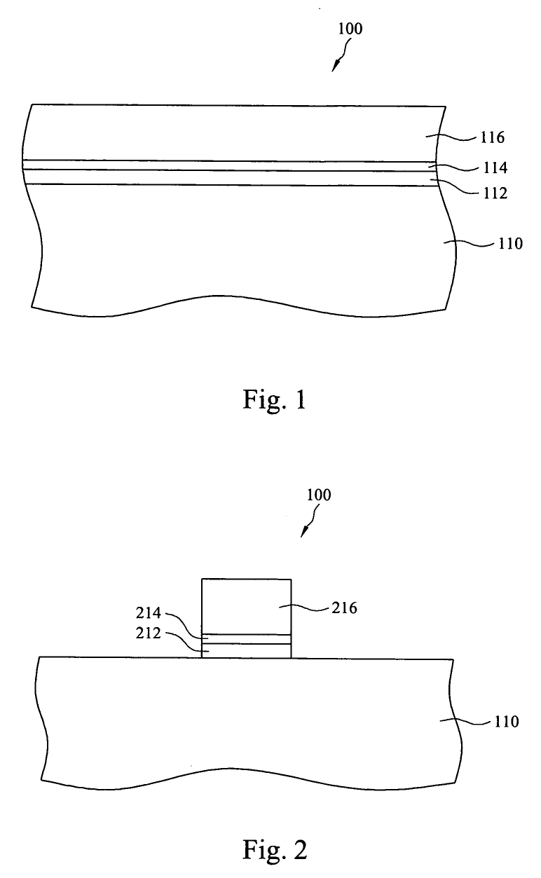

FIGS. 1-3 illustrate a method embodiment for fabricating a semiconductor device having a gate structure with a deuterated layer in accordance with an embodiment of the present invention. Embodiments of the present invention illustrated herein may be used in a variety of circuits. In particular, embodiments of the present invention are particularly useful for sub-65 nm transistor designs in which dopant penetration into the substrate may be particularly troublesome.

Referring first to FIG. 1, a structure 100 comprising a substrate 110 having a first dielectric layer 112, a deuterated layer 114, and a conductive layer 116 formed thereon is shown in accordance with an embodiment of the present invention. The substrate 110 may comprise bulk silicon, doped or undoped, or an active layer of a semiconductor-on-insulator (SOI) substrate. Generally, an SOI comprises a layer of a semiconductor material, such as silicon, formed on an insulator layer. The insulator layer may be, for example, a buried oxide (BOX) layer or a silicon oxide layer. The insulator layer is generally provided on a substrate, typically a silicon or glass substrate. Other substrates, such as a multi-layered or gradient substrate, may also be used.

The first dielectric layer 112, from which a gate dielectric layer will be formed, may be an oxide layer thermally grown at a temperature of about 600° C. to about 900° C. to a thickness of about 7 Å to about 14 Å. Other materials, such as silicon oxide, silicon oxynitride, silicon nitride, nitrogen-containing oxide, aluminum oxide, lanthanum oxide, hafnium oxide, zirconium oxide, hafnium oxynitride, combinations thereof, or the like, may be used. Preferably, the first dielectric layer 112 has a relative permittivity value greater than about 4. The first dielectric layer 112 may also be formed, for example, by chemical vapor deposition (CVD) techniques using tetra-ethyl-ortho-silicate (TEOS) and oxygen as a precursor. Other processes and materials may be used.

The deuterated layer 114 (also referred to as a deuterium layer) may be an oxynitride layer, which will form part of a gate dielectric, and preferably comprises a portion of the first dielectric layer 112 that has been nitridated using an isotope of hydrogen, such as deuterium. Preferably, the deuterated layer 114 has a thickness of about 0.5 Å to about 1 Å. The deuterated layer 114 may be formed by performing an anneal treatment on the first dielectric layer 112 in a gaseous ambient containing a hydrogen isotope, such as deuterated ammonia (ND3). The anneal may be performed at a temperature of about 800° C. to about 1000° C. a pressure of about 10 torr to about 100 torr, and a process time of about 5 minutes to 20 minutes.

In another embodiment, the deuterated layer 114 may be formed by performing a plasma treatment on the first dielectric layer 112 in a gaseous ambient containing a hydrogen isotope, such as deuterated ammonia (ND3). In this embodiment, the deuterated layer 114 may be formed using a power of about 850-1500 watts, a pressure of about 20-60 mTorr, a temperature of about 300° C. to about 900° C., and a flow rate of about 500-8000 sccm. It should be noted that the plasma nitridation process allows a lower process temperature than the thermal process described above. Other processes, such as a UV process, an e-beam process, or the like, may be used.

The conductive layer 116, from which a gate electrode will be formed, preferably comprises a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In one example, the conductive layer 116 may be formed by depositing doped or undoped poly-silicon by low-pressure chemical vapor deposition (LPCVD) to a thickness in the range of about 500 Å to about 1500 Å, but more preferably about 1000 Å. The poly-silicon may be doped with an N-type dopant or a P-type dopant.

FIG. 2 illustrates the structure 100 after the first dielectric layer 112, the deuterated layer 114, and the conductive layer 116 of FIG. 1 have been patterned to form a gate dielectric 212, a gate deuterated layer 214, and a gate electrode 216, respectively. The gate dielectric 212, gate deuterated layer 214, and gate electrode 216 may be patterned by photolithography techniques known in the art. Generally, photolithography involves depositing a photoresist material, which is then masked, exposed, and developed. After the photoresist mask is patterned, an etching process may be performed to remove unwanted portions of the first dielectric layer 112, the deuterated layer 114, and the conductive layer 116 (see FIG. 1) to form the gate dielectric 212, gate deuterated layer 214, and gate electrode 216 as illustrated in FIG. 2. In an embodiment in which the gate electrode material is poly-silicon, the gate deuterated layer is deuterated oxynitride, and the gate dielectric is silicon oxide, the etching process may be a wet or dry, anisotropic or isotropic, etch process, but preferably is an anisotropic dry etch process.

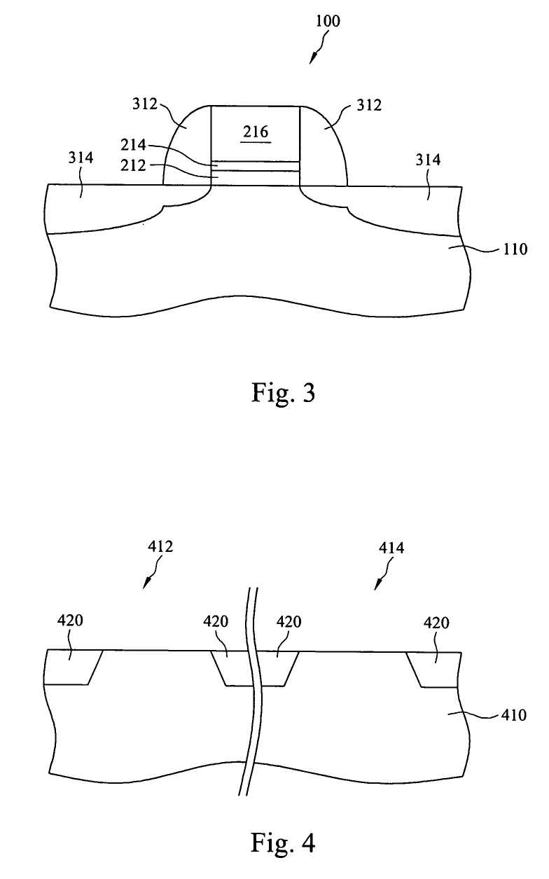

FIG. 3 illustrates structure 100 after spacers 312 and source/drain regions 314 have been formed in accordance with an embodiment of the present invention. Source/drain regions 314 may be formed by ion implantation. The source/drain regions 314 may be implanted with an n-type dopant, such as phosphorous, nitrogen, arsenic, antimony, or the like, to fabricate NMOS devices or may be implanted with a p-type dopant, such as boron, aluminum, indium, or the like, to fabricate PMOS devices. Optionally, NMOS devices may be fabricated on the same chip as PMOS devices. In this optional embodiment, it may be necessary to utilize multiple masking and ion implant steps as are known in the art such that only specific areas are implanted with n-type and/or p-type ions.

Spacers 312, which form spacers for a second ion implant in the source/drain regions 314, preferably comprise silicon nitride (Si₃N₄), or a nitrogen-containing layer other than Si₃N₄, such as SiₓN_{y}, silicon oxynitride SiOₓN_{y}, silicon oxime SiOₓN_{y}:H_{z,}or a combination thereof. In a preferred embodiment, the spacers 312 are formed from a layer comprising Si₃N₄ that has been formed using chemical vapor deposition (CVD) techniques using silane and ammonia (NH₃) as precursor gases. In an alternative embodiment, the spacers 312 are formed of a deuterated silicon nitride formed by CVD techniques using deuterated silane and deuterated ammonia (ND3) as source gases.

The spacers 312 may be patterned by performing an isotropic or anisotropic etch process, such as an isotropic etch process using a solution of phosphoric acid (H₃PO₄). Because the thickness of the layer of Si₃N₄ (or other material, including deuterated silicon nitride) is greater in the regions adjacent to the gate electrode 216, the isotropic etch removes the Si₃N₄ material on top of the gate electrode 216 and the areas of substrate 110 not immediately adjacent to the gate electrode 216, leaving the spacer 312.

It should be noted that a silicidation process may be performed. The silicidation process may be used to improve the conductivity of the gate electrode 216, as well as to decrease the resistance of source/drain regions 314. The silicide may be formed by depositing a metal layer such as titanium, nickel, tungsten, or cobalt via plasma vapor deposition (PVD) procedures. An anneal procedure causes the metal layer to react with the gate electrode 216 and the source/drain regions 314 to form metal silicide. Portions of the metal layer overlying the spacers 312 remain unreacted. Selective removal of the unreacted portions of the metal layer may be accomplished, for example, via wet etch procedures. An additional anneal cycle may be used if desired to alter the phase of silicide regions, which may result in a lower resistance.

It should also be noted that the above description illustrates an example of one type of a transistor that may be used with an embodiment of the present invention and that other transistors and other semiconductor devices may also be used. For example, the transistor may have raised source/drains, the transistor may be a split-gate transistor or a FinFET design, different materials and thicknesses may be used, liners may be used between the spacer and the gate electrode, or the like.

Embodiments of the present invention may provide increased resistance against dopant penetration and impurities due to a more chemically stable oxynitride layer through the introduction of deuterium. As a result, the deuterium bonding in CMOS devices reduces hot-carrier degradation and improves device reliability. Furthermore, the resulting structure exhibits improved capacitance-voltage (C-V) characteristics and enhanced channel conductance due to stable deuterated chemical bonding.

FIGS. 4-8 illustrate an embodiment for fabricating a semiconductor device having a gate structure with a deuterated layer in a core region and/or an I/O region in accordance with an embodiment of the present invention. It should be noted that FIGS. 4-8 illustrate an embodiment in which the I/O region includes a thicker gate dielectric than the core region for illustrative purposes only. While this embodiment may be particularly useful due to the higher currents expected in the I/O region as compared to the core region, other combinations may be used as appropriate for a specific application.

Referring first to FIG. 4, a substrate 410 having a core region 412 and an I/O region 414 is provided. The substrate may have one or more isolation features, such as shallow trench isolations (STIs) 420, to isolate the core region 412 and the I/O region 414, as well as to isolate separate devices within each of the core region 412 and the I/O region 414. The substrate 410 may be similar to the substrate 110 discussed above with reference to FIG. 1. The STIs 420 may be formed by etching trenches in the substrate and filling the trenches with a dielectric material, such as silicon dioxide, a high-density plasma (HDP) oxide, or the like.

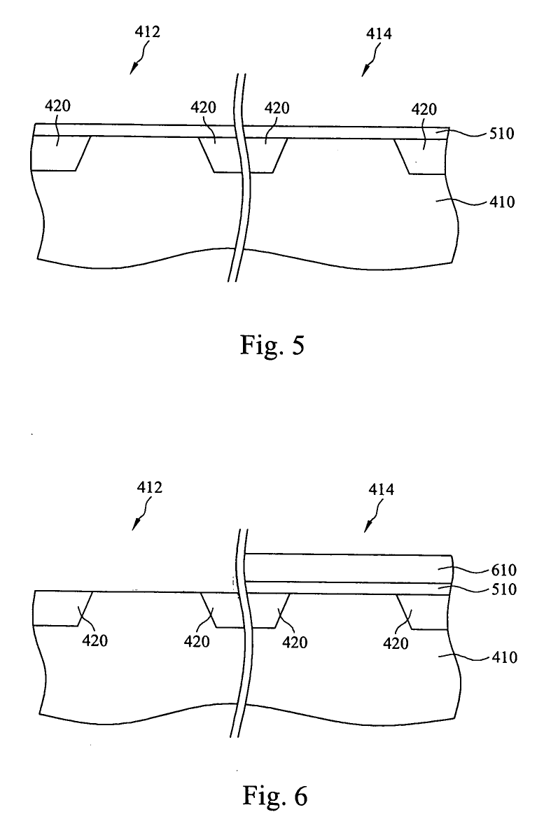

In FIG. 5, a first dielectric layer 510 has been formed over the substrate 410 in accordance with an embodiment of the present invention. The first dielectric layer 510 may be silicon oxide, silicon oxynitride, silicon nitride, nitrogen-containing oxide, aluminum oxide, lanthanum oxide, hafnium oxide, zirconium oxide, hafnium oxynitride, combinations thereof, or the like. Preferably, the first dielectric layer 510 has a relative permittivity value greater than about 4. The first dielectric layer 510 may be formed by an oxidation process, such as wet or dry thermal oxidation in an ambient comprising H₂O, NO, or a combination thereof, or by chemical vapor deposition (CVD) techniques using tetra-ethyl-ortho-silicate (TEOS) and oxygen as a precursor. In a preferred embodiment, the first dielectric layer 510 is thermally grown at a temperature of about 600° C. to about 900° C. to a thickness of about 7 Å to about 28 Å.

FIG. 6 illustrates the removal of at least a portion of the first dielectric layer 510 from the surface of the substrate 410 in the core region 412 in accordance with an embodiment of the present invention. The removal of at least a portion of the first dielectric layer 510 within the core region 412 allows a thinner gate dielectric to be formed with the core region 412, which typically requires a thinner gate dielectric than the I/O region 414 due to the lower currents used in the core region 412.

The first dielectric layer 510 may be removed from core region 412 by photolithography techniques followed by an etching process as is known in the art. Generally, a photoresistive material is deposited, exposed, and developed to form a photoresist mask 610 illustrated in FIG. 6. After the photoresist mask is patterned, an etching process may be performed to remove the exposed portion of the first dielectric layer 510 in the core region. The etching process may be a wet or dry, anisotropic or isotropic, etch process, but preferably is an anisotropic dry etch process. The remaining portions of the photoresist mask 610 may be removed after the etching process.

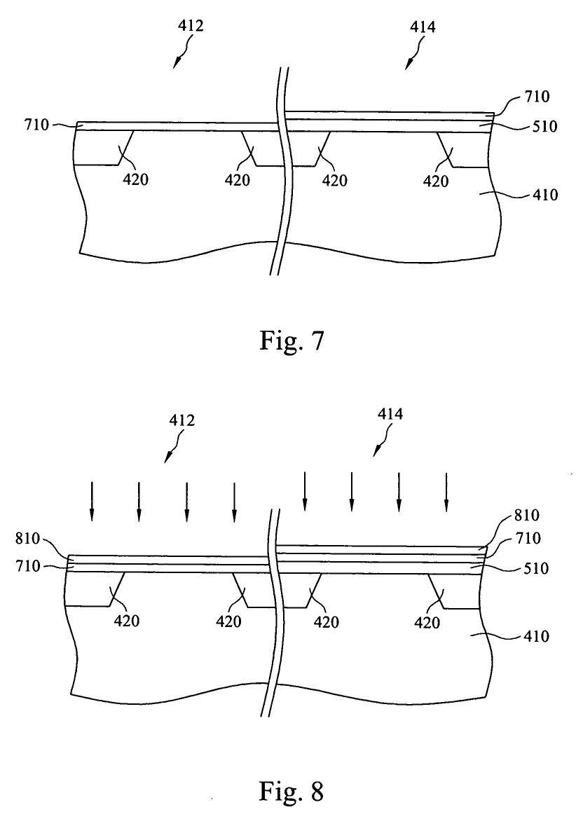

FIG. 7 illustrates the semiconductor device after a second dielectric layer 710 has been formed in accordance with an embodiment of the present invention. The second dielectric layer 710 may be formed in a similar manner as described above with reference to the first dielectric layer 510. Other materials and processes, however, may be used. In a preferred embodiment, the second dielectric layer 710 is thermally grown at a temperature of about 600° C. to about 900° C. to a thickness of about 7 Å to about 14 Å.

FIG. 8 illustrates a treatment performed to at least a portion of the second dielectric layer 710 in accordance with an embodiment of the present invention. The treatment may be a treatment with a hydrogen isotope, such as deuterium. Suitable treatments are discussed above with reference to the deuterated layer 114 (see FIG. 1). As a result of the treatment described above, at least a portion of the second dielectric layer 710 is deuterated, as indicated by deuterated layer 810. Preferably, the deuterated layer 810 has a thickness of about 0.5 Å to about 10 Å.

It should be noted that in an embodiment, the second dielectric layer 710 may be substantially deuterated. Furthermore, in yet another embodiment, the second dielectric layer 710 may be substantially deuterated and at least a portion of the first dielectric layer 510 may be deuterated. In yet other embodiments, it may be preferred to mask either the core region 412 or the I/O region 414 to prevent or reduce the deuteration of the first dielectric layer 510 and/or the second dielectric layer 710.

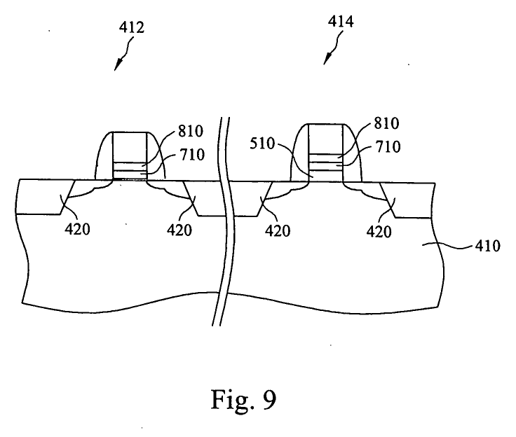

Thereafter, standard processing techniques may be used to pattern the first dielectric layer 510, the second dielectric layer 710, and the deuterated layer 810, form spacers, implant the source/drain regions, and form a gate electrode as described above with reference to FIGS. 2 and 3. FIG. 9 illustrates an example of a transistor that may be formed in the core region 412 and the I/O region 414 in accordance with an embodiment of the present invention.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor device on a substrate, the method comprising:
forming a dielectric layer on the substrate;
transforming at least a portion of the dielectric layer into a deuterium layer;
forming a conductive layer on the deuterium layer;
patterning the deuterium layer and the conductive layer to form a gate deuterium layer and a gate electrode; and
forming source/drain regions on either side of the gate electrode.

2. The method of claim 1, wherein the transforming is performed by thermally transforming the dielectric layer into a deuterated oxynitride layer.

3. The method of claim 2, wherein the thermally transforming is performed in a gaseous ambient of deuterated ammonia.

4. The method of claim 2, wherein the thermally transforming is performed at a temperature between about 800° C. and about 1000° C.

5. The method of claim 1, wherein the transforming is performed by a plasma nitridation process.

6. The method of claim 5, wherein the plasma nitridation process is performed in a gaseous ambient of deuterated ammonia.

7. The method of claim 5, wherein the plasma nitridation process is performed at a temperature between about 300° C. and about 900° C.

8. The method of claim 1, wherein the dielectric layer has a thickness between about 7 Å and about 14 Å.

9. The method of claim 1, wherein the gate deuterium layer has a thickness between about 0.5 Å and about 10 Å.

10. The method of claim 1, wherein the gate electrode has a thickness between about 500 Å and about 1500 Å.

11. A method of forming a semiconductor device on a substrate, the method comprising:
forming a dielectric layer on the substrate;
annealing the substrate in an ambient comprising deuterium, the annealing deuterating at least a part of the dielectric layer to form a deuterated oxynitride layer;
forming a conductive layer on the deuterated oxynitride layer;
patterning the deuterated oxynitride layer and the conductive layer to form a gate deuterated layer and a gate electrode; and
forming source/drain regions on either side of the gate electrode.

12. The method of claim 11, wherein the annealing is performed in a gaseous ambient of deuterated ammonia.

13. The method of claim 11, wherein the annealing is performed at a temperature between about 800° C. and about 1000° C.

14. The method of claim 11, wherein the dielectric layer has a thickness between about 7 Å and about 14 Å.

15. The method of claim 11, wherein the gate deuterated layer has a thickness between about 0.5 Å and about 10 Å.

16. A method of forming a semiconductor device on a substrate, the method comprising:
forming a first dielectric layer on a first portion and a second portion of the substrate;
removing at least a portion of the first dielectric layer on the first portion;
forming a second dielectric layer on the substrate and the first dielectric layer; and
transforming at least a portion of the second dielectric layer into a third layer, the transforming using a hydrogen isotope.

17. The method of claim 16, wherein the transforming is performed by thermally annealing the second dielectric layer in a gaseous ambient of deuterated ammonia.

18. The method of claim 17, wherein the thermally annealing is performed at a temperature between about 800° C. and about 1000° C.

19. The method of claim 16, wherein the transforming is performed by a plasma nitridation process in a gaseous ambient of deuterated ammonia.

20. The method of claim 19, wherein the plasma nitridation process is performed at a temperature between about 300° C. and about 900° C.
